(19) United States
(12) Patent Application Publication
(10) Pub. No.: US 2008/0237580 A1
(43) Pub. Date: Oct. 2, 2008

(54) Organic Semiconductor Element and Organic El Display Device Using the Same

(76) Inventors: Suguru Okuyama, Kyoto-shi (JP); Noriyuki Shimoji, Kyoto-shi (JP)

Correspondence Address: RABIN & Berdo, PC, 1101 14TH STREET, NW, SUITE 500, WASHINGTON, DC, 20005, US

(21) Appl. No.: 10/593,726

(22) PCT Filed: Mar. 17, 2005
(86) PCT No.: PCT/JP2005/004818

§ 371 Date: Sep. 21, 2006

(30) Foreign Application Priority Data
Mar. 22, 2004 (JP) 2004-083309

(51) Int. Cl. H01L 51/00

(52) U.S. Cl. 257/40; 257/E51.001

(57) ABSTRACT

It is provided an organic semiconductor element having an FET which can control a channel length to a small value and does not cause a rise in contact resistance due to a step portion, and an organic light emitting display device with a large aperture using the same. A first conductive layer (2) which is one of source/drain electrodes is provided onto a substrate (1), and an organic semiconductor layer (3) and a second conductive layer (4) which is the other electrode of the source/drain electrodes are provided onto the first conductive layer (2). Then on a side face of the organic semiconductor layer or a front surface of the organic semiconductor layer (3) exposed by removing a part of the second conductive layer and a side face of the second conductive layer a gate electrode (third conductive layer) (6) is provided via an insulating layer (5), thereby to form an FET. The organic EL display device has the FET having such structure laminated on an organic EL section as a drive element.

### TECHNICAL FIELD

The present invention relates to an organic semiconductor element including a field-effect transistor (hereinafter, FET) or the like using an organic semiconductor, and an organic EL display device using the same. More specifically, the present invention relates to an organic semiconductor element which can make a channel length very short while using an organic semiconductor and can compose a display device only by laminating an organic EL section, and an organic EL display device using the same.

### BACKGROUND ART

As structures of conventional FETs using organic semiconductor layers, structures shown in FIGS. 9A to 9C are known. That is, the structure shown in FIG. 9A is called a bottom contact (BC) structure. For example, a pair of source/drain electrodes 33 and 34 are provided onto an insulating film 32 on a gate electrode 31 composed of a silicon substrate, and an organic semiconductor layer 35 is provided thereon, so that the organic semiconductor layer 35 between the source/drain electrodes 33 and 34 is used as a channel region. In this structure, since the source/drain electrodes can be formed by using the photolithography technique, they can be formed by partially fine patterns. However, since the organic semiconductor layer 35 is provided to a step portion of the source/drain electrodes, the coverage of the organic semiconductor layer 35 is not satisfactory. As a result, a gap 36 is easily generated between the organic semiconductor layer 35 to be the channel region and bottom corner portions of the electrodes 33 and 34, thereby increasing contact resistance.

The structure shown in FIG. 9B is called a top contact (TC) structure. The organic semiconductor layer 35 is provided onto the insulating film 32 on the gate electrode 31, and the source/drain electrodes 33 and 34 are provided thereon, so that the organic semiconductor layer 35 under and between the source/drain electrodes 33 and 34 is used as the channel region. This structure does not have the problem of the coverage of the organic semiconductor layer 35. However, after the organic semiconductor layer 35 is formed, the electrodes should be formed. With an organic semiconductor material, a pattern cannot be formed by the photolithography technique in which the material is exposed to a solvent or an alkali aqueous solution; therefore, the organic semiconductor layer 35 should be formed by using a shadow mask (metal mask) made of a metal plate. The shadow mask has a resolving power of about 25 μm; consequently, a fine pattern cannot be formed and the channel length cannot be shortened.

The structure shown in FIG. 9C is called a top and bottom contact (TBC) structure. One electrode 33 of the source/drain electrodes is partially provided onto the insulating film 32, and the organic semiconductor layer 35 is provided thereon and on the exposed portion of the insulating film 32, and the other electrode 34 of the source/drain electrodes is provided thereon. As a result, the organic semiconductor layer 35 between a side surface of one electrode 33 of the source/drain electrodes and a step of the other electrode 34 is used as the channel region (for example, see Patent Document 1). In this structure, since the channel length can be controlled by a thickness of the organic semiconductor layer 35, the channel length can be easily shortened or lengthened. However, similarly to the BC type, the organic semiconductor layer is formed on the step portion of the source/drain electrode 33. For this reason, its coverage is not satisfactory, so that the contact resistance rises.

Patent Document 1: JP2003-258265A (for example, FIG. 4)

### DISCLOSURE OF THE INVENTION

### Problems to be Solved by the Invention

In conventional FETs using the organic semiconductors, when the organic layer has the step portion, the coverage is not satisfactory, so that the contact resistance is high. When a flat organic semiconductor layer is tried to be used, the fine source/drain electrodes cannot be formed, so that the channel length cannot be shortened. In any structures, the channel with low resistance cannot be formed.

Due to such a circumstance, even in active display devices using organic EL semiconductors, for example, the organic semiconductor element cannot be used as its driving element, and a silicon semiconductor made of polysilicon or the like is used as the driving element. For this reason, both the organic semiconductor and the silicon semiconductor should be used. In the case where the driving element is formed by the silicon semiconductor, the photolithography technique should be indispensably used. However, since the photolithography technique cannot be used after the organic semiconductor is formed, the driving element cannot be formed on the organic EL section. On the other hand, when the driving element is formed on a substrate side, light should be taken out from the surface side. However, in order to realize this, an electrode to be arranged thereon should be a translucent electrode. On the other hand, after an organic EL semiconductor layer is laminated, high-temperature heat treatment cannot be used. Since, however, the translucent electrode with low resistance generally requires the high-temperature treatment, it cannot be formed on the surface side. For this reason, as shown in a plan explanatory view of FIG. 5D, mentioned later, a light emitting section Land a driving element section (Tr and a capacitor CAPA) should be separated in a plan view, and thus an area of a display section becomes small and an aperture becomes small.

The present invention is devised in order to solve such problems, and its object is to provide an organic semiconductor element having an FET which can control a channel length to a small value and does not cause a rise in contact resistance due to a step portion.

It is another object of the present invention to provide an active type organic light emitting display device where all semiconductor layers are composed of organic semiconductor layers, a light emitting section, a driving element and a capacitor section are formed into a laminated structure, and a display section has large aperture.

### Means for Solving the Problems

An organic semiconductor element having an FET of the present invention includes; a substrate, a first conductive layer which is one of source/drain electrodes and is provided onto the substrate, an organic semiconductor layer provided onto the first conductive layer, a second conductive layer which is the other electrode of the source/drain electrodes and is provided onto the organic semiconductor layer, and a gate electrode provided onto a side surface of the organic semiconductor layer or a surface of the organic semiconductor layer exposed by partially eliminating the second conductive layer and a side surface of the second conductive layer via an insulating layer.

When an organic semiconductor layer which reduces an energy barrier is provided between the first conductive layer and the organic semiconductor layer and/or between the second conductive layer and the organic semiconductor layer, an electric current can be allowed to flow by a low operating voltage, and thus this structure is preferable. In the structure of the present invention, the organic semiconductor layer is sandwiched by the source/drain electrodes, and both the surfaces of the organic semiconductor layer contact with the source/drain electrodes, thereby producing the great effect.

An organic EL display device of the present invention includes; a translucent substrate, a translucent electrode provided onto the translucent substrate, an EL organic layer provided onto the translucent electrode, and a driving element, a switching element, and a capacitor, which are provided on the EL organic layer by laminating, wherein the driving element includes a vertical transistor formed of a laminated structure of a first conductive layer, a first organic semiconductor layer and a second conductive layer, and a gate electrode provided at least on a side surface of the second conductive layer via an insulating layer. The EL organic layer means a portion of the organic semiconductor layers laminated so as to form the organic EL section (the portion where the electrode and the organic semiconductor layer are laminated so as to form a light emitting section). Further, in the case where the first conductive layer composing the driving element is laminated on the organic EL section, the first conductive layer can be shared by the electrode of the organic EL section or the EL organic layer of the organic EL section can be used in place of the first conductive layer.

The switching element may be formed by a vertical FET which is configured so that the driving element is provided onto the EL organic layer, a part of a third conductive layer for a gate electrode formed on an upper surface of the driving element is one of source/drain electrodes of the switching element, and an organic semiconductor layer and a fourth conductive layer as the other electrode of the source/drain electrodes are formed on the part of the third conductive layer. Further, the driving element and the switching element are provided separately in a driving element region and a switching element region on the EL organic layer in a plan view. And the switching element may be a lateral FET in which the organic semiconductor layer for the switching element is formed continuously or simultaneously with the organic semiconductor layer of the driving element and a pair of source/drain electrodes is provided on the same surface of the organic semiconductor layer so as to be spaced.

In a concrete structure, the first organic semiconductor layer for the driving element is provided on the EL organic layer, the second conductive layer as one of the source/drain electrodes for the driving element is provided partially on the first organic semiconductor layer, a first insulating layer as a gate insulating film for the driving element is provided on an exposed surface, a third conductive layer as the gate electrode for the driving element and as one of the source/drain electrodes for the switching element is provided on the first insulating layer, a second organic semiconductor layer for the switching element is provided on the third conductive layer in a switching element region provided with the switching element, a fourth conductive layer as the other electrode of the source/drain electrodes for the switching element is provided partially on the second organic semiconductor layer, a second insulating layer as a dielectric layer of the capacitor and as a gate insulating film for the switching element is provided on the third conductive layer in a driving element region provided with the driving element, and the exposed portion of the second organic semiconductor layer and the fourth conductive layer in the switching element region, a fifth conductive layer as a gate electrode for the switching element is provided on the second insulating layer in the switching element region, and a sixth conductive layer as an electrode of the capacitor is provided on the second insulating layer in the driving element region.

According to this structure, the gate electrode of the driving element and the source/drain electrodes of the switching element can be formed continuously and simultaneously and all the elements can be formed only by laminating them sequentially. The elements can be formed by a very simple manufacturing step, and the electrode of the capacitor and the gate electrode of the driving element can be used as a shared electrode.

In a still another concrete structure, a third insulating layer is provided on the EL organic layer in the switching element region, the first organic semiconductor layer for the driving element and the switching element is provided on the third insulating layer and the EL organic layer in the driving element region, the second conductive layer as the other electrode of the source/drain electrodes for the driving element is provided partially on the first organic semiconductor layer in the driving element region, seventh and eighth conductive layers as the source electrode and the drain electrode for the switching element are provided on the first organic semiconductor layer in the switching element region so as to be separated, a first insulating layer as a gate insulating film for the driving element is provided on an exposed portion of the first organic semiconductor layer and the second conductive layer in the driving element region, a fourth insulating layer as a gate insulating film for the switching element is provided on an exposed portion of the first organic semiconductor layer and the seventh and eighth conductive layers in the switching element region so that a part of the seventh or eighth conductive layer is exposed, a third conductive layer as a gate electrode for the driving element is provided on the first insulating layer so as to be electrically connected to the exposed portion of the seventh or eighth conductive layer, a fifth conductive layer as a gate electrode for the switching element is provided on the fourth insulating layer, a second insulating layer as a dielectric layer of the capacitor is provided on the third conductive layer, and a sixth conductive layer as an electrode of the capacitor is provided on the second insulating layer.

With this structure, since the organic semiconductor layer for the driving element and the organic semiconductor layer for the switching element can be formed continuously and simultaneously, the organic semiconductor layer which is formed as a key process can be formed by one forming step. In this case, the switching element is the lateral FET, but as its channel length does not have to be finer, so that the source/drain electrodes can be formed by using a shadow mask.

An upper electrode of the organic EL section and the first conductive layer as one of the source/drain electrodes of the driving element are provided as a common conductive layer or separate conductive layers between the EL organic layer and the first organic semiconductor layer. As a result, the electric current can be diffused by the first conductive layer with low resistance over the entire organic display section, light is emitted even on a portion under the switching element, and the light can be emitted brightly in the entire structure. As a result, this structure is preferable.

### EFFECTS OF THE INVENTION

With the structure of the organic semiconductor element of the present invention, the channel region is formed on the side surface of the organic semiconductor layer or the portion of the organic semiconductor layer where the gate electrode near the side surface of the second conductive layer is opposed to the first conductive layer, and the channel length is determined by the thickness of the organic semiconductor layer. For this reason, the channel length can be controlled very accurately in nanometer order. Further, the organic semiconductor layer and the source/drain electrodes are formed into a flat laminated structure, so that the problem of coverage due to a step does not arise. As a result, the contact resistance reduces, and a FET having desired channel length can be formed into an accurate dimension. For this reason, transistor properties such as an increase in the drain current and a decrease in the operating voltage can be improved greatly.

Further, since the gate electrode is formed on an upper surface, in the case where, for example, one of the source/drain of the switching element is connected to the gate electrode of the driving element in the display device, or where a control circuit in which the capacitor is connected to the gate of the driving element, the circuit can be formed simply by laminating the layers on the upper surface sequentially. Particularly when this organic semiconductor layer is applied to the organic light emitting (EL) display device, the display device can be formed by laminating the organic semiconductor layer and the organic EL section (light emitting section).

As a result, while the organic semiconductor is being used, the semiconductor element having an FET with very short channel length can be obtained, and the channel length can be controlled by the thickness of the organic semiconductor layer. For this reason, the FET with very definite channel length in nanometer order can be formed without using the photolithography technique, and it can be used as the driving element of the organic light emitting (EL) display device. Further, the FET can be formed only by the simple laminated structure or the channel portion is formed in a self-consistent manner, the process cost can be reduced, and the FET can be obtained at the very low cost.

Further, due to the structure of the organic EL display device of the present invention, even when the driving element is not obtained by the photolithography technique, the FET with short channel length and very low contact resistance can be obtained. Further, the driving element and the capacitor can be formed on the organic EL section only by the simple laminated structure, and the driving element or the like does not have to be arranged in parallel with the display section, so that the most part of each pixel area can be formed by the organic EL section. As a result, the aperture can be improved very greatly, and the organic EL display device which can provide clear display can be obtained at the very low cost. Further, since the electric current flows to the vertical direction in the driving element having the vertical structure, the electric current flows continuously with the organic EL section. For this reason, no useless path is present and even when the electric current can be allowed to flow by the low resistance and the upper electrode of the organic EL section and the source/drain electrodes on the lower surface for the driving element are not provided, the electric current can be allowed to flow from the driving element to the organic EL section. As a result, the active-matrix type organic light emitting (EL) display device with high performance can be obtained at the low cost, thereby contributing to the new progress of image display devices.

### BRIEF DESCRIPTION OF THE DRAWINGS

FIG. 1 is an explanatory diagram illustrating a sectional structure of an organic semiconductor element according to one embodiment of the present invention.

FIGS. 2A to 2D are sectional explanatory diagrams illustrating the manufacturing steps of the organic semiconductor element shown in FIG. 1.

FIGS. 3A and 3B are sectional explanatory diagrams illustrating the organic semiconductor element according to another embodiment of the present invention.

FIG. 4 is a sectional explanatory diagram illustrating the organic semiconductor element according to still another embodiment of the present invention.

FIGS. 5A to 5D are diagrams explaining a schematic configuration of an organic EL display device according to one embodiment of the present invention.

FIG. 6 is a diagram explaining a configuration example of an organic EL section in FIG. 1.

FIG. 7 is a sectional explanatory diagram illustrating a concrete configuration example of the organic EL display device according to the present invention.

FIG. 8 is a sectional explanatory diagram illustrating a concrete configuration example of the organic EL display device according to the present invention.

FIGS. 9A to 9C are sectional explanatory diagrams of conventional organic semiconductor elements.

### EXPLANATION OF SYMBOLS

1: Substrate
2: First conductive layer
3: Organic semiconductor layer (first organic semiconductor layer)
4: Second conductive layer
5: Insulating layer (first insulating layer)
6: Gate electrode (third conductive layer)
7: Second organic semiconductor layer
8: Fourth conductive layer
9: Second insulating layer
10: Fifth conductive layer
11: Sixth conductive layer
12: Third insulating layer
13: Seventh conductive layer
14: Eighth conductive layer
15: Fourth insulating layer

### BEST MODE FOR CARRYING OUT THE INVENTION

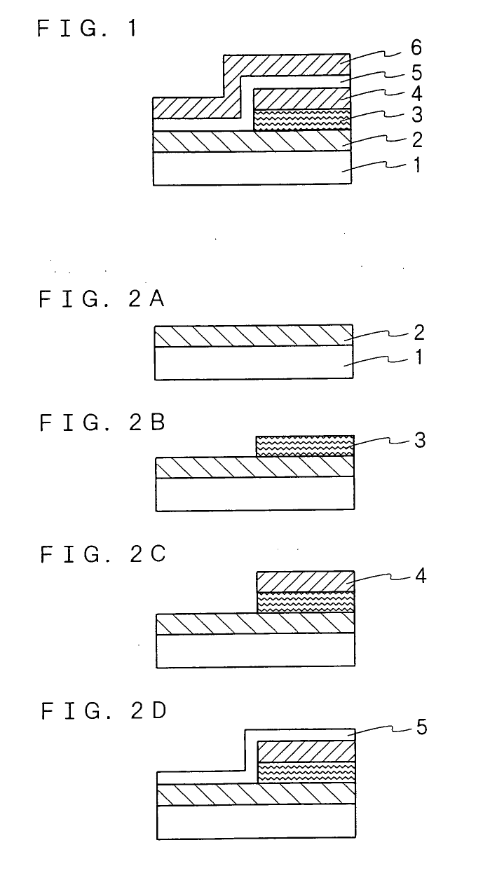

An organic semiconductor element of the present invention and an organic EL display device using the same are explained below with reference to the drawings. In the organic semiconductor element of the present invention, as shown in the sectional explanatory diagram of one embodiment in FIG. 1, a first conductive layer 2 which is one of source/drain electrodes is provided onto a substrate 1, and an organic semiconductor layer 3 and a second conductive layer 4 which is the other electrode of the source/drain electrodes are provided onto the first conductive layer 2. In the example shown in FIG. 1, the organic semiconductor layer 3 and the second conductive layer 4 are formed so as to be smaller than the first conductive layer 2, and a part of the first conductive layer 2 is exposed. A gate electrode (third conductive layer) 6 is provided to the surface of the first conductive layer 2 via an insulating layer 5 as a gate insulating film so that an FET is formed. The substrate 1 is very thicker than the other layers, but the thickness relationship is not shown in the drawings.

As the substrate 1, inorganic materials such as glass, sintered alumina, various insulating plastics such as a polyimide film, a polyester film, a polyethylene film, a polyphenylene sulfide film and a polyparaxylene film, hybrid materials of these inorganic substances and organic substances, or a conductive substrate such as a semiconductor substrate which is used also as the first conductive layer may be used. Respective films of the organic semiconductor elements are laminated according to objects on the substrate 1, and the substrate 1 may have strength which is sufficient for holding a device. In the case where the organic semiconductor element is used as an organic EL display device, mentioned later, the substrate means an entire substrate where an organic light emitting section is formed. In the case where only the organic semiconductor element is manufactured, when a plastic substrate is used, a light-weighted and flexible organic TFT can be manufactured.

As the first conductive layer 2 and the second conductive layer 4 for the source/drain electrodes, metal, conductive organic (inorganic) materials or complex materials of them, which have excellent conductivity and good adhesiveness between the substrate and the organic semiconductor layer and low contact resistance, are used. Concretely, in order to obtain ohmic contact with a p-type organic semiconductor layer, metal having large work function is preferable, namely, gold and platinum are used preferably. The material of the conductive layers is not limited to these material. In the case where the surface of the semiconductor layer is doped with dopant with high density, carriers can tunnel between the metal and the semiconductors, and thus the conductive layers are not influenced by the material of the metal, so that metal materials which are mentioned later as a gate electrode can be used. The conductive layers 2 and 4 are formed into a thickness of about 20 to 200 nm with which they can be used as the low-resistance layers, and preferably a thickness of about 50 to 100 nm.

As the organic semiconductor layer 3, materials, which has a high on/off ratio, excellent carrier transport performance and good adhesiveness with the insulating layers and the electrode materials, are used, and π-conjugated system aromatic compounds, chain compounds, organic pigment, organic silicon compounds and the like can be used. Concretely, pentacene, tetracene, thiophene oligomer derivatives, phenylene derivatives, phthalocyanine compound, polyacetylene derivatives, polythiophene derivatives, cyanine pigment and the like can be used, but the organic semiconductor layer 3 is not limited to them. The organic semiconductor layer 3 is formed into a thickness of about 50 to 5000 nm according to a desired channel length, preferably about 100 to 1000 nm.

Preferable examples of the material of the insulating layer 5 as the gate insulating film are organic materials such as polychloropyrene, polyethylene terephthalate, polyoxymethylene, polyvinyl chloride, polyvinylidene fluoride, ceanoethyl pullulan, polymethyl methacrylate, polysulfone, polycarbonate and polyimide which can use the applying method. Further, inorganic materials such as SiO₂, SiNₓ and Al₂O₃ which can use an existent pattern process can be used. The insulating layer 5 is not limited to these materials, and if they are used, two or more kinds of them can be used simultaneously. Since the insulating layer 5 has excellent insulating property and secures a break-down voltage which can withstand a voltage applied to the gate electrode, it is formed into a thickness of about 10 to 1000 nm, preferably about 50 to 100 nm.

As the gate electrode (third conductive layer) 6, organic materials such as polyaniline and polythiophene which can use an applying method for a simple electrode forming process, or electrically conductive ink are desirable. Metals such as gold, platinum, chrome, palladium, aluminum, indium, molybdenum and nickel, metal alloy using these metals, inorganic materials such as tin oxide, indium oxide and indium-tin oxide (ITO) can be used in a sputtering method or a vacuum deposition method using a shadow mask. Further, silicon, polysilicon and amorphous silicon can be also used. Two or more kinds of these materials may be used simultaneously.

One concrete example of the method of manufacturing the organic semiconductor element is explained with reference to the step diagrams shown in FIGS. 2A to 2D. As shown in FIG. 2A, the first conductive layer 2 as one of the source/drain electrodes is formed by the vacuum deposition method or the like. The first conductive layer 2 can be formed also by applying an electrically conductive organic material, for example. The shadow mask is provided, and as shown in FIG. 2B, the organic semiconductor layer 3 is formed so that the first conductive layer 2 is partially exposed. The same mask is used and the second conductive layer 4 as the other electrode of the source/drain electrodes is formed on the organic semiconductor layer 3 as shown in FIG. 2C. Thereafter, the insulating layer 5 is formed on the entire surface. The gate electrode 6 is formed on the surface of the insulating layer 5. As a result, an FET having a sectional structure shown in FIG. 1 is formed. In the above method, the respective layers are formed by the vacuum deposition method, but they can be formed also by the applying method.

According to the organic semiconductor element of the present invention, the gate electrode 6 is formed via the insulating layer 5 on the side surface of the organic semiconductor layer 3 sandwiched between the first and the second conductive layers 2 and 4 as the source/drain electrodes. For this reason, the side surface of the organic semiconductor layer 3 opposed to the gate electrode 6 of the organic semiconductor layer 3 becomes a channel region, and the channel is ON or OFF by the control of the gate electrode 6 so that the FET is operated.

In this structure, since interfaces between the organic semiconductor layer 3 and the first and the second conductive layers 2 and 4 as the source/drain electrodes are flat and has high adhesiveness, contact resistance is very low. Since the insulating layer 5 and the gate electrode 6 are formed on a step portion between the organic semiconductor layer 3 and the first conductive layer 2, coverage is not good and thus the corner portions are not possibly filled sufficiently with the insulating layer, but since an electric current does not originally flow in the insulating layer 5, the contact resistance does not become a problem.

Furthermore, since the channel length is determined by a thickness of the organic semiconductor layer 3, when the film deposition thickness is controlled, the desired channel length can be obtained. The thickness of the organic semiconductor layer 3 can be obtained in nanometer order, and the channel length can be controlled in nanometer order. Further, since the laminated structure is simple and the channel portion is formed in a self-aligned manner, the manufacturing is easy and the process cost can be reduced greatly. As a result, a high drain current can be obtained by a low operating voltage, and the FET with high property can be obtained at the low cost. For this reason, the organic semiconductor element can be used sufficiently as a driving element of an organic light emitting display device which is driven by an electric current, and the driving element is laminated continuously on the organic EL section so that the organic EL display device can be configured.

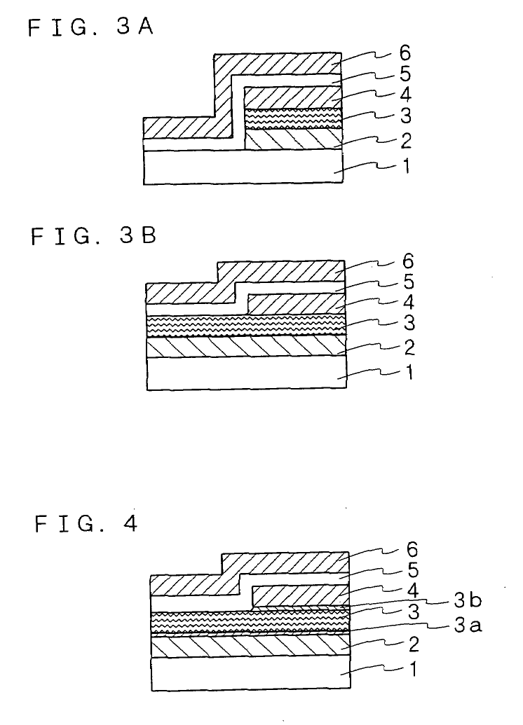

In the structure shown in FIGS. 1 and 2A to 2D, the organic semiconductor layer 3 and the second conductive layer 4 are deposited so as to be partially lacked, and the gate electrode is formed on their side surfaces via the insulating layer. However, when this structure is not always adopted, with structures of modified examples shown in FIGS. 3A and 3B, similarly, an FET where the thickness of the organic semiconductor layer 3 is the channel length can be operated.

That is, in the structure shown in FIG. 3A, the first conductive layer 2 is formed not on the entire surface but formed so as to be partially lacked. With this structure, since the gate electrode 6 is opposed to the side surface of the organic semiconductor layer 3 more completely, the on/off state of the channel region can be controlled by a low gate voltage. The other portions are the same as the example shown in FIG. 1, and like portions are designated by like numerals, and the explanation thereof is omitted.

Further, in the structure shown in FIG. 3B, on the contrary, also the organic semiconductor layer is provided to the entire surface, and only the second conductive layer 4 is formed so as to be partially lacked. The gate electrode 6 is provided to the side surface of the second conductive layer 4 and the exposed surface of the organic semiconductor layer via the insulating layer 5. With this structure, the organic semiconductor layer 3 near the side surface of the second conductive layer 4 is the channel region, and the on/off state can be controlled by the gate electrode 6. In this example, the other portions are same as the example shown in FIG. 1, and like portions are designated by like reference numerals and the explanation thereof is omitted. With this structure, in the case where a plurality of driving elements are arranged in parallel, only the second conductive layer 4 may be formed into a pattern, so that the manufacturing process becomes simple.

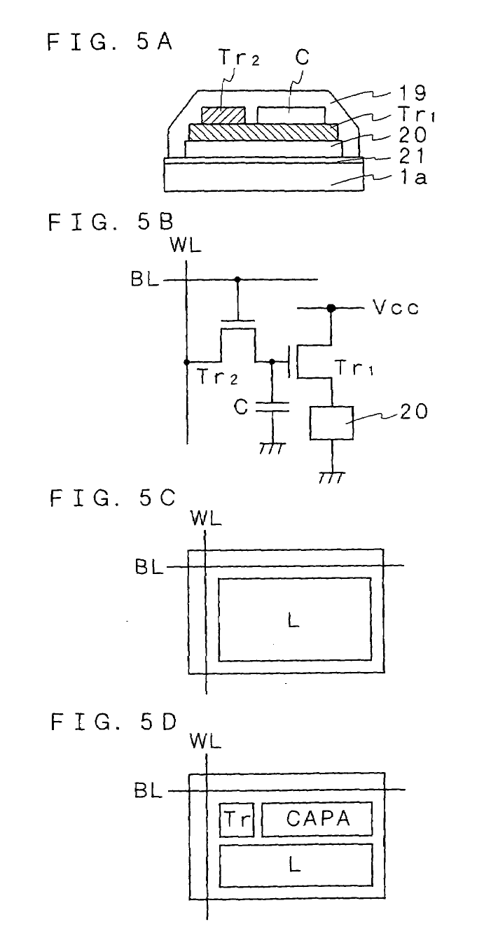

FIG. 4 is a sectional explanatory diagram similar to FIG. 1 showing the organic semiconductor element according to another embodiment of the present invention, and injection and taking-out of the drain current are further improved. That is, source/drain layers (carrier injection layers) 3a and 3b are formed on the interface between the first conductive layer 2 and the organic semiconductor layer 3, and the second conductive layer 4 and the organic semiconductor layer 3, respectively. The source/drain layers 3a and 3b are organic semiconductor layers for making an energy barrier small between the source/drain electrodes 2 and 4 and the organic semiconductor layer 3. When the energy barrier between the organic semiconductor layer 3 and the source/drain electrodes 2 and 4 becomes small, the carriers are easily injected and taking out, so that the lower contact resistance is obtained, and the high drain current can be obtained by the low driving voltage.

In the organic FET of the present invention, since the source/drain electrodes 2 and 4 are provided on both the upper and lower surfaces of the organic semiconductor layer 3, the source/drain layers 3a and 3b for making the electric current easily flow are provided to both ends of the channel region, thereby producing an effect which is equivalent to that the density of impurity in the source/drain region is heightened by a silicon semiconductor layer and an electric current easily flows. That is, in the conventional structure where the source/drain electrodes are provided to one surface of the organic semiconductor layer, since an electric current channel extends in a lateral direction on the surface of the organic semiconductor layer, it is difficult to provide the source/drain layers 3a and 3b on portions other than the channel region. However, in the present invention, due to the simple laminated structure, the source/drain layers 3a and 3b can be easily provided.

As the source/drain layers (carrier injection layers) 3a and 3b, for example, CuPc (copper phthalocyanine), PANI (polyaniline), PEDOT (poly-3,4-ethylenedioxy-thiophene) and the like can be used.

FIGS. 5A to 5C are diagrams illustrating schematic configuration of the organic EL display device using the above FET of the present invention. That is, in the organic EL display device of the present invention, a translucent electrode 21 is provided onto a translucent substrate 1a, and an organic EL section 20 is provided onto the translucent electrode 21. Further, a driving element Tr₁, a switching element Tr₂ and a capacitor C are provided onto the organic EC section 20 in a laminated manner, and the driving element Tr₁ is composed of a vertical FET having the above structure. That is, in such a display device, in order to display a fine image, as shown in an equivalent circuit diagram for one pixel in FIG. 5B, the organic EL section 20 is connected between a power source line Vcc and an earth via the driving element Tr₁, a gate of the driving element Tr₁ is connected to the switching element Tr₂, and a word line WL and a bit line BL compose a matrix so that an active type display device which can select respective pixels is configured.

In the present invention, when the organic FET having the above structure is used as the driving element Tr₁, the FET having a short channel length can be formed by the organic semiconductor without using the photolithography technique, and it can be laminated on the organic EL section 20. For this reason, as shown in a plan explanatory view for one pixel of FIG. 5C, the approximately entire surface of the pixels can be a light emitting section L, and areas for conventional transistor Tr and capacitor CAPA shown in FIG. 5D do not have to be secured, so that the area of the light emitting section L can be enlarged more greatly than the conventional structures.

As the substrate 1a, in order to take out light from the substrate side, a translucent glass substrate or a plastic film is used. Further, as the translucent electrode 21, ITO (Indium Tin Oxide), indium oxide or the like which is provided by the vacuum deposition method or the sputtering method is used.

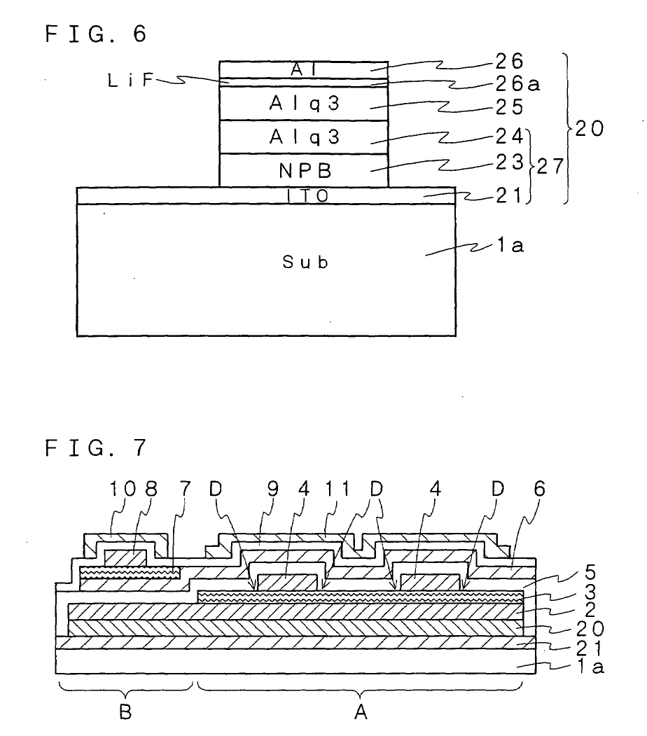

The organic EL section 20 is formed so that, as shown in FIG. 6, for example, an EL organic layer 27 composed of a hole transport layer 23, a light emitting layer 24 and an electron transport layer 25 is provided on the translucent electrode 21 on the glass substrate Sub1a, and the other electrode (upper surface electrode) 26 is laminated thereon sequentially. However, the EL organic layer 27 is not limited to this three-layered structure, and thus at least the light emitting layer may be formed and the respective layers can be multiple layers.

As to the hole transport layer 23, in order to improve a property of injecting the hole into the light emitting layer 24 and stable transport of the hole, it is generally necessary that the energy of ionization is small to some extent and confining of electrons into the light emitting layer 24 (energy barrier) is possible. Amine series materials such as triphenyldiamine derivatives, styrylamine derivatives and amine derivatives having aromatic condensing ring are used, and it is provided into a thickness of 10 to 100 nm, preferably about 20 to 50 nm. Although not shown, a hole injecting layer is provided between the hole transport layer 23 and an anode electrode 21, so that the property of injecting carriers into the hole transport layer 23 can be further improved. Also in this case, in order to improve the property of injecting the hole from the anode electrode 21, a material with good conformity of ionizing energy is used, and its typical example is amine series or phthalocyanine series materials are used. In the example shown in FIG. 6, as the hole transport layer 23, NPB with thickness of 35 nm is provided.

As to the light emitting layer 24, an organic fluorescent material using Alq3 as a base material which is selected according to a luminous wavelength is doped so that a luminescent color which is specific to the doping material can be obtained, and the luminous efficiency and the stability can be improved. This doping is carried out on the luminescent material at about a several weight (wt) % (0.1 to 20 wt %).

Examples of the luminescent material are quinacridone, rubrene, and styryl series pigment. Further, quinoline derivatives, tetraphenyl butadiene, anthracene, perylene, coronene, 12-pthaloperynone derivatives, phenylanthracene derivatives, tetraarylethene derivatives and the like can be used. Further, it is preferable that these materials are combined with host substances which can emit light by itself. As the host substance, quinolinorate complex is preferable, 8-quinolinol or aluminum complex whose ligand is the 8-quinolinol derivative is preferable, and phenylanthracene derivatives, tetraarylethene derivatives or the like can be used.

The electron transport layer 25 has a function for improving the property of injecting electrons from a cathode electrode 26 and a function for transporting electrons stably, and in the example shown in FIG. 6, Alq3 (tris(8-quinolinorate) aluminum) is provided so as to have a thickness of about 25 nm. When this layer becomes too thick, series resistance component becomes large, and thus the thickness is not too large, namely, normally the thickness is 10 to 80 nm, and preferably 20 to 50 nm. As the electron transport layer 25, besides the above materials, quinoline derivatives, 8-quinollinol, metal complex whose ligand is 8-quilinol derivatives, phenylanthracene derivatives, tetraarylethene derivatives or the like can be used. In the case where a gap between the electron transport layer 25 and the cathode electrode 26 is large, similarly to the hole side, an electron injecting layer 26a composed of LiF or the like is provided.

As the cathode electrode 26, in order to improve the electron injecting property, metal whose work function is small is mainly used. Its examples are generally Mg, K, Li, Na, Ca, Sr, Ba, Al, Ag, In, Sn, Zn and Zr. Further, translucent conductive film such as indium oxide can be also used. In order to prevent such metal from being oxidized and stabilize the metal, metal alloy of the metal and an other metal is mostly used. In the example shown in FIG. 6, an Al layer is deposited into about 110 nm via the LiF layer 26a so that the cathode electrode 26 is formed.

Since the driving element Tr₁ is connected to the organic EL section 20 serially, when the channel length becomes long, the resistance increases, and the electric current to be supplied to the organic EL section 20 reduces. For this reason, an FET with short channel length is preferable, and the vertical organic FET having the structure shown in FIG. 1 or 3A to 3B is used. Since this FET is of vertical type, even if the first conductive layer 2 as the source/drain electrodes shown in FIG. 1 or 3A to 3B and the electrode 26 of the organic EL section 20 shown in FIG. 6 are not provided, the electric current directly flows in the organic EL section 20 so that the organic EL section 20 can emit light. However, when the first conductive layer which is commonly used as both the electrodes is provided, the electric current which passes through the driving element Tr₁ is diffused to the entire surface by the first conductive layer. For this reason, the electric current can be supplied to the entire organic EL section 20, and thus the first conductive layer is preferable for light emission on a wide area.

On the other hand, since a switching element Tr₂ does not require much electric current, although the organic FET having the structure shown in FIG. 1 or FIGS. 3A to 3B may be used, this structure does not have to be adopted and a conventional lateral type FET may be formed by using a shadow mask. The capacitor C is used for holding the ON state of the driving element for a determined time, and it is formed so as to have capacity for retaining data.

A concrete structural example is explained in detail below. FIG. 7 illustrates an example in which the vertical organic FET is used for both the driving element Tr₁ and the switching element Tr₂. That is, the translucent electrode 21 composed of, for example, ITO is formed on the translucent substrate 1a made of, for example, glass, so that the organic EL section 20 having the structure shown in FIG. 6 is laminated. The first conductive layer 2 which is commonly used as the upper electrode of the organic EL section and one of the source/drain electrodes of the driving element is formed thereon. The first conductive layer 2 does not have to be formed unlike the above structure. The organic semiconductor layer 3 is laminated in a driving element region A on its surface, and the second conductive layer 4 which is the other electrode of the source/drain electrodes is provided partially on the surface of the organic semiconductor layer 3 (two places in FIG. 7). The first insulating layer 5 as a gate insulating film is provided on the entire surface of the second conductive layer 4, and the third conductive layer 6 as a gate electrode is provided on the surface of the first insulating layer 5, so that the organic FET having the above structure is formed as the driving element Tr₁.

In the switching element region B, the third conductive layer 6 is one of the source/drain electrodes, and a second organic semiconductor layer 7 for switching element is laminated on the surface of the third conductive layer 6. A fourth conductive layer 8 as the other one of the source/drain electrodes is provided partially on the surface of the second organic semiconductor layer 7, and a second insulating layer 9 as a gate insulating film for a switching element and an insulating film for a capacitor is provided on the surface of the fourth conductive layer 8 and the third conductive layer 6 in the driving element region A. A fifth conductive layer 10 as the gate electrode for the switching element is formed on the second insulating layer 9 in the switching element region B, and a sixth conductive layer 11 as a capacitor electrode is formed on the second insulating layer in the driving element region A simultaneously by the same material. A protective film 19 (see FIG. 5A) is formed on the surfaces of the fifth conductive layer 10 and the sixth conductive layer 6, so that the organic light emitting display device having the structure shown in the schematic diagram of FIG. 5A is obtained.

In this structure, a channel region of the driving element Tr₁ is formed on a portion D of the first organic semiconductor layer 3 where the side end of the second conductive layer 4 is opposed to the first conductive layer 2. When the channel is ON, an electric current flows to a vertical direction in a portion D, and an electric current flows in the organic EL section 20 below the portion D so that light is emitted. For this reason, when the width of the second conductive layer 4 is made to be as small as possible and a lot of them is formed, the number of the channel regions can be increased. Further, the channel width is made to be large and the electric current easily flows, and thus this structure is preferable. It is preferable that the band-shaped second conductive layers 4 are continuously formed in a direction vertical to the paper surface.

In the example shown in FIG. 7, the two second conductive layers 4 are formed. In the case, for example, where a display device in which the size of one pixel is 300 μm×300 μm is configured, when one pixel is composed of three colors: R, G and B, the sizes of R, G and B in one pixel are 100 μm×300 μm. As a result, more second conductive layers 4 can be formed (formed continuously into a band shape in a direction of 300 μm or 100 μm).

In the example shown in FIG. 7, the driving element Tr₁ is not formed below the switching element Tr₂. However, since the third conductive layer 6 is the top surface of the driving element Tr₁, although its height becomes slightly high, the switching element Tr₂ can be formed on the driving element Tr₁, and as shown in FIG. 7, it is not necessary that the driving element region A is separated from the switching element region B in a plan view.

In the example shown in FIG. 7, the structure is such that the first organic semiconductor layer 3 and the first conductive layer 2 are provided to the approximately entire surface of the driving element region (the structure of the organic semiconductor element shown in FIG. 3B). However, even in the structure of the organic semiconductor element shown in FIG. 1 or 3A, the vertical FET can be formed, and the first organic semiconductor layer 3 or the first conductive layer 2 can be formed according to the pattern of the second conductive layer 4.

Further in the example shown in FIG. 7, the switching element Tr₂ is also the vertical FET, and similarly to the example of the driving element Tr₁, the channel region is formed on the second organic semiconductor layer 7 near the side end of the fourth conductive layer 8. However, the switching element Tr₂ does not require much electric current, and fourth conductive layer 8 may be formed in only one region, and the driving element can be formed behind the fourth conductive layer 8 (the direction vertical to the paper surface). When the driving element Tr₁ is formed on the entire surface of the pixel, since the electric current can be supplied from the driving element Tr₁ directly to the approximately entire surface of the organic EL section 20, non-presence of the first conductive layer 2 does not interfere with the operation.

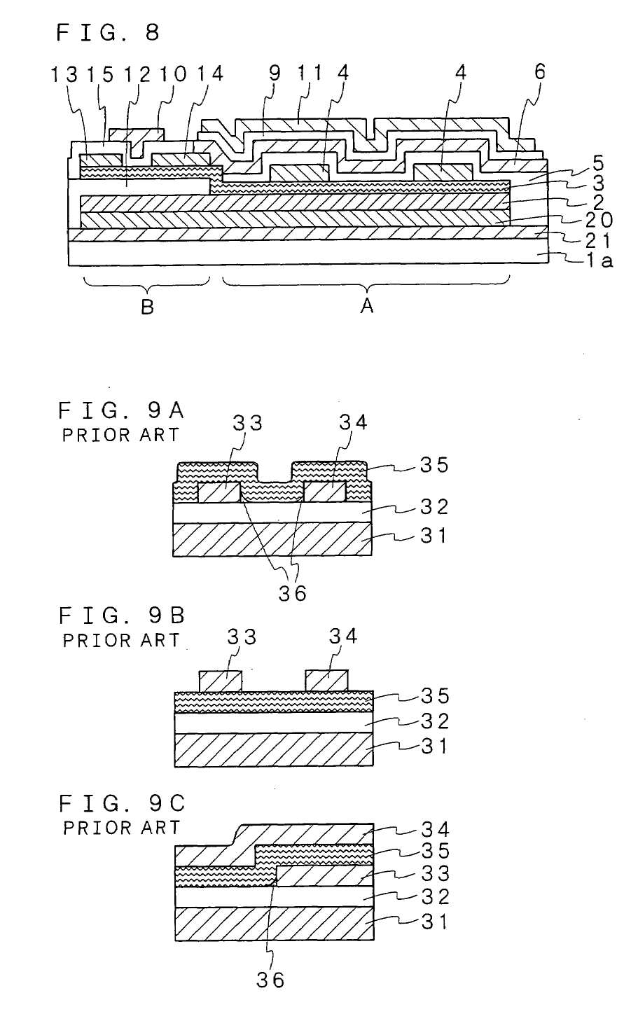

FIG. 8 illustrates an example where the switching element Tr₂ is composed of not the vertical FET but the conventional lateral FET. Since the switching element Tr₂ does not require much electric current, even if the channel length is not short, a problem does not arise. For this reason, even the FET having the conventional structure using a shadow mask has no problem. As to the example shown in FIG. 8, the portion up to the first conductive layer 2 is the same as the example shown in FIG. 7, and after the first conductive layer 2 is formed, a third insulating layer 12 is provided in the switching element region B. The first organic semiconductor layer 3 for the driving element and the switching element is laminated on the third insulating layer 12 and the first conductive layer 2 in the driving element region A, and the second conductive layer 4 is formed thereon in the driving element region A, and seventh and eighth conductive layers 13 and 14 which are simultaneously as the source/drain electrodes for switching element are formed in the switching element region B by the same material as the second conductive layer 4 so as to be separated by a predetermined gap.

The insulating film is deposited so that one of the source/drain electrodes for the switching element, for example, a part of the eighth conductive layer 14 is exposed, and the first insulating film 5 as the gate insulating film for the driving element and a fourth insulating film 15 as the gate insulating film for the switching element are provided. The first insulating layer 5 and the fourth insulating layer 15 may be continuously formed, but the eighth conductive layer 14 is formed so as to be partially exposed. The third conductive layer 6 as the gate electrode for the driving element is provided onto the first insulating layer 5 in the driving element region A so as to contact with the eighth conductive layer 14, and the fifth conductive layer 10 as the gate electrode for the switching element is provided between the source/drain electrodes 13 and 14 on the fourth insulating layer 15 in the switching element region B. The sixth conductive layer 11 as the electrode of the capacitor is provided on the third conductive layer 6 in the driving element region A via the second insulating layer 9, so that the organic light emitting display device is formed. In FIG. 8, the portions corresponding to those in FIG. 7 are designated by the same reference numerals as FIG. 7.

In this structure, the structure on the driving element side is the same as that shown in FIG. 7, but since the FET on the switching element side is of the lateral type, the organic semiconductor layers of both elements are formed simultaneously by one layer of the first organic semiconductor layer 3. However, in the structure shown in FIG. 7, the gate electrode of the driving element and one of the source/drain electrodes of the switching element are formed simultaneously by the third conductive layer 6, but in the structure shown in FIG. 8, both the source/drain electrodes 13 and 14 of the switching element Tr₂ are formed simultaneously with the other electrode 4 of the source/drain electrodes of the driving element Tr₁. For this reason, the gate electrode 6 of the driving element is formed so as to contact with the other electrode 14 of the source/drain electrodes of the switching element. According to this structure, the organic semiconductor layers 3, (formation of this layer is a key process), of both the elements can be formed simultaneously by the same layer, and the number of the manufacturing step can be reduced. Needless to say, the layers 3 do not have to be formed simultaneously by the same layer.

In the example shown in FIG. 8, the organic semiconductor layer for the driving element and the organic semiconductor layer for the switching element are continuously formed by one layer, but they may be separated. However, they can be formed simultaneously by the same material and by one step. Further, in the structure shown in FIG. 8, the seventh and eighth conductive layers 13 and 14 as the source/drain electrodes for the switching element are formed on the upper side of the first organic semiconductor layer 3 but can be formed on the lower side of the organic semiconductor layer 3. The seventh and the eight conductive layers 13 and 14 as the source/drain electrodes can be formed on the upper side of the organic semiconductor layer 3, and the fifth conductive layer 10 as the gate electrode can be formed on the lower side of the organic semiconductor layer 3.

As shown in FIGS. 7 and 8, according to the organic EL display device of the present invention, since the FET for the driving element is provided onto the organic EL section, the electrode on the connecting portion between the organic EL section and the driving element can be shared or both the electrodes can be omitted. Further, since the capacitor is formed on the gate electrode of the driving element, the electrode can be shared by both of them. Further, since the switching element is laminated on the gate electrode of the driving element or is formed simultaneously with the respective layers of the driving element, the active matrix type organic light emitting display device can be obtained only by simple laminating.

Furthermore, since all the driving element, the switching element and the capacitor are formed on the organic EL section, the area of the display section is not reduced due to the driving element; thus, the aperture can be considerably improved. Further, since the organic EL section is formed first on the ITO electrode on the light emitting surface side, the resistance of the translucent electrode can be reduced sufficiently, so that the luminous efficiency can be improved.

### INDUSTRIAL APPLICABILITY

The organic semiconductor element of the present invention can be utilized in integrated circuits for electronic devices such as portable displays and electronic tags including electronic price tag and electronic shipping tags which are supplied at low cost. The organic EL display device of the present invention can be utilized in displays of cellular telephones, mobile computers and flat-screen televisions.

1. An organic semiconductor element in clouding an FET comprising:
a substrate;
a first conductive layer which is one of source/drain electrodes and is provided onto the substrate;
an organic semiconductor layer provided onto the first conductive layer;
a second conductive layer which is the other electrode of the source/drain electrodes and is provided onto the organic semiconductor layer; and
a gate electrode provided onto a side surface of the organic semiconductor layer or a surface of the organic semiconductor layer exposed by partially eliminating the second conductive layer and a side surface of the second conductive layer via an insulating layer.

2. The organic semiconductor element according to claim 1, wherein an organic semiconductor layer which reduces an energy barrier is provided between the first conductive layer and the organic semiconductor layer and/or between the second conductive layer and the organic semiconductor layer.

3. The organic semiconductor element according to claim 1, wherein the first conductive layer is provided over a wide range, the organic semiconductor layer and the second conductive layer are provided onto the first conductive layer so that their side surfaces are exposed together, and the gate electrode is provided via the insulating layer so as to cover the side surfaces of the organic semiconductor layer and the second conductive layer.

4. The organic semiconductor element according to claim 1, wherein the first conductive layer, the organic semiconductor layer and the second conductive layer are provided so that their side surfaces are exposed together, and the gate electrode is provided via the insulating layer so as to cover the side surfaces of the first conductive layer, the organic semiconductor layer and the second conductive layer.

5. The organic semiconductor element according to claim 1, wherein the first conductive layer and the organic semiconductor layer are provided over a wide range, the second conductive layer is provided onto the organic semiconductor layer so that its side surface is exposed, and the gate electrode is provided via the insulating layer so as to cover the side surface of the second conductive layer.

6. An organic EL display device comprising:
a translucent substrate;
a translucent electrode provided onto the translucent substrate;
an EL organic layer provided onto the translucent electrode; and
a driving element, a switching element and a capacitor, which are provided on the EL organic layer by laminating,
wherein the driving element comprises a vertical transistor formed of a laminated structure of a first conductive layer, a first organic semiconductor layer and a second conductive layer, and a gate electrode provided at least on a side surface of the second conductive layer via an insulating layer.

7. The organic EL display device according to claim 6, wherein an upper electrode of an organic EL section and the first conductive layer as one of source/drain electrodes of the driving element are provided as a common conductive layer or separated conductive layers between the EL organic layer and the driving element.

8. The organic EL display device according to claim 6, wherein the switching element is formed by a vertical FET which is configured so that the driving element is provided onto the EL organic layer, a part of a third conductive layer for a gate electrode formed on an upper surface of the driving element is one of source/drain electrodes of the switching element, and an organic semiconductor layer and a fourth conductive layer as the other electrode of the source/drain electrodes are laminated on the part of the third conductive layer.

9. The organic EL display device according to claim 6,
wherein the driving element and the switching element are provided separately in a driving element region and a switching element region on the EL organic layer in a plan view, and
wherein the switching element is a lateral FET in which the organic semiconductor layer for the switching element is formed continuously or simultaneously with the organic semiconductor layer of the driving element and a pair of source/drain electrodes are provided on the same surface of the organic semiconductor layer so as to be spaced.

10. The organic EL display device according to claim 8, wherein the first organic semiconductor layer for the driving element is provided on the EL organic layer, the second conductive layer as one of the source/drain electrodes for the driving element is provided partially on the first organic semiconductor layer, and further comprising:
a first insulating layer as a gate insulating film for the driving element provided on an exposed surface;
a third conductive layer as the gate electrode for the driving element and as one of the source/drain electrodes for the switching element provided on the first insulating layer;
a second organic semiconductor layer for the switching element provided on the third conductive layer in a switching element region provided with the switching element;
a fourth conductive layer as the other electrode of the source/drain electrodes for the switching element provided partially on the second organic semiconductor layer;
a second insulating layer as dielectric layer of the capacitor and as a gate insulating film for the switching element provided on the third conductive layer in a driving element region provided with the driving element, and the exposed portion of the second organic semiconductor layer and the fourth conductive layer in the switching element region;
a fifth conductive layer as a gate electrode for the switching element provided on the second insulating layer in the switching element region; and
a sixth conductive layer as an electrode of the capacitor provided on the second insulating layer in the driving element region.

11. The organic EL display device according to claim 9, wherein a third insulating layer is provided on the EL organic layer in the switching element region, the first organic semiconductor layer for the driving element and the switching element is provided on the third insulating layer and the EL organic layer in the driving element region, and the second conductive layer as the other electrode of the source/drain electrodes for the driving element is provided partially on the first organic semiconductor layer in the driving element region, further comprising:
seventh and eighth conductive layers as the source electrode and the drain electrode for the switching element provided on the first organic semiconductor layer in the switching element region so as to be separated;
a first insulating layer as a gate insulating film for the driving element provided on an exposed portion of the first organic semiconductor layer and the second conductive layer in the driving element region;
a fourth insulating layer as a gate insulating film for the switching element provided on an exposed portion of the first organic semiconductor layer and the seventh and eighth conductive layers in the switching element region so that a part of the seventh or eighth conductive layer is exposed;
a third conductive layer as a gate electrode for the driving element provided on the first insulating layer so as to be electrically connected to the exposed portion of the seventh or eighth conductive layer;
a fifth conductive layer as a gate electrode for the switching element provided on the fourth insulating layer;
a second insulating layer as a dielectric layer of the capacitor provided on the third conductive layer; and
a sixth conductive layer as an electrode of the capacitor provided on the second insulating layer.

12. The organic EL display device according to claim 10, wherein an upper electrode of the organic EL section and the first conductive layer as one of the source/drain electrodes of the driving element are provided as a common conductive layer or separate conductive layers between the EL organic layer and the first organic semiconductor layer.

13. The organic EL display device according to claim 11, wherein an upper electrode of the organic EL section and the first conductive layer as one of the source/drain electrodes of the driving element are provided as a common conductive layer or separate conductive layers between the EL organic layer and the first organic semiconductor layer.
